(19) United States
(12) Patent Application Publication
(10) Pub. No.: US 2012/0032301 A1
(43) Pub. Date: Feb. 9, 2012

(54) SEMICONDUCTOR DEVICE

(75) Inventors: Takeo KASUGA, Sendai-shi (JP); Koji SAKATA, Sendai-shi (JP); Takeshi SAITO, Sendai-shi (JP)

(73) Assignee: NEC TOKIN CORPORATION, Sendai-shi (JP)

(21) Appl. No.: 13/198,374

(22) Filed: Aug. 4, 2011

(30) Foreign Application Priority Data
Aug. 6, 2010 (JP) 2010-176888

(51) Int. Cl. H01L 29/92

(52) U.S. Cl. 257/532; 257/E29.342

(57) ABSTRACT

A semiconductor device includes a lead frame including an island, a power supply lead, and a GND lead; a sheet-like solid electrolytic capacitor that is mounted on the island; a semiconductor chip that is mounted on the solid electrolytic capacitor, a plane area of the semiconductor chip being smaller than that of the solid electrolytic capacitor; a bonding wire that connects the semiconductor chip and the solid electrolytic capacitor, and a bonding wire that connects the solid electrolytic capacitor and the power supply lead or the GND lead, in which at least the connection part between the anode plate and the anode part of the solid electrolytic capacitor and the connection part between the anode plate and the bonding wire do not overlap when being vertically projected.

### INCORPORATION BY REFERENCE

This application is based upon and claims the benefit of priority from Japanese patent application No. 2010-176888, filed on Aug. 6, 2010, the disclosure of which is incorporated herein in its entirety by reference.

### BACKGROUND OF THE INVENTION

1. Field of the Invention

The present invention relates to a semiconductor device, and more specifically, to a semiconductor device including a sheet-like solid electrolytic capacitor combined with a semiconductor chip.

2. Description of Related Art

In recent years, several techniques of providing a capacitor between a ground circuit and a power supply circuit of a semiconductor chip including an LSI to stably supply electric power have been disclosed. A bypass capacitor included in a semiconductor package and arranged in a position that is close to the circuit of the semiconductor chip including the LSI achieves shorter wiring length, reduces equivalent series inductance (ESL), and provides the LSI that efficiently and stably operates. Further, by mounting the bypass capacitor in the semiconductor package, the number of elements arranged on a motherboard can be reduced.

A semiconductor device including a semiconductor chip, a solid electrolytic capacitor, and a bonding wire is disclosed, for example, in Japanese Unexamined Patent Application Publication No. 2005-294291. FIG. 10 shows a cross-sectional view showing one example of related complex electronic components. The semiconductor device includes a solid electrolytic capacitor 25 arranged and attached onto a semiconductor chip 11. The technique of connecting the semiconductor chip 11 and the solid electrolytic capacitor 25 includes a method of connecting an anode pad 21 and a cathode pad 22, and a method of connecting an end surface of an anode terminal (anode via 16) formed by performing conductor plating processing on a hole formed in an upper surface of an insulating resin so as to reach an anode member of the solid electrolytic capacitor 25 and a land (anode pad 21) formed in an upper surface of a substrate 20 by bonding wire. Farther, while description has been made above regarding the anode part, a cathode conducting layer of the solid electrolytic capacitor may be connected by the similar method.

According to the semiconductor device disclosed in Japanese Unexamined Patent Application Publication No. 2005-294291, the position at which the bonding wire connects with the solid electrolytic capacitor is the connection part between the anode member of the solid electrolytic capacitor and the anode terminal obtained by performing conductor plating processing on the hole. Therefore, weight or vibration caused by a bonding tool at the time of wire bonding may destroy the connection part between the anode member of the sheet-like solid electrolytic capacitor immediately below the wire bonding part and the anode terminal formed by conductor plating, which may cause conduction failure. Thus, there is a problem in connection reliability.

### SUMMARY OF THE INVENTION

In short, the present invention aims to provide a semiconductor device with high reliability.

The present invention provides means for solving the aforementioned problem, and an exemplary configuration of which will be described below.

A first exemplary aspect of the present invention is a semiconductor device including a lead frame comprising an island, a power supply lead, and a GND lead; a sheet-like solid electrolytic capacitor that is mounted on the island; a semiconductor chip that is mounted on the solid electrolytic capacitor, a plane area of the semiconductor chip being smaller than that of the solid electrolytic capacitor; a bonding wire that connects the semiconductor chip and the solid electrolytic capacitor; and a bonding wire that connects the solid electrolytic capacitor and the power supply lead or the GND lead, in which the semiconductor device includes a connection part between an anode plate welded to an anode part of the solid electrolytic capacitor and the anode part and a connection part between the anode plate and the bonding wire, the connection part between the anode plate and the anode part and the connection part between the anode plate and the bonding wire do not overlap when being vertically projected.

A second exemplary aspect of the present invention is a semiconductor device including a lead frame comprising an island, a power supply lead, and a GND lead; a sheet-like solid electrolytic capacitor that is mounted on the island; a semiconductor chip that is mounted on the solid electrolytic capacitor through a substrate, a plane area of the semiconductor chip being smaller than that of the solid electrolytic capacitor; a bonding wire that connects the semiconductor chip and the solid electrolytic capacitor through the substrate; and a bonding wire that connects the solid electrolytic capacitor and the power supply lead or the GNU lead through the substrate, in which the semiconductor device includes a connection part between an anode plate welded to an anode part of the solid electrolytic capacitor and the anode part and a connection part between the substrate and the bonding wire, the connection part between the anode plate and the anode part and the connection part between the substrate and the bonding wire do not overlap when being vertically projected.

According to the present invention, the connection part of the anode plate welded to the anode part of the solid electrolytic capacitor with the anode part, and the connection part between the anode plate and the bonding wire, or the connection part between the substrate and the bonding wire are arranged in different positions when they are vertically projected, thereby being capable of preventing occurrence of connection failure or conduction failure due to impact caused by weight or vibration of a bonding tool.

According to the present invention, when the anode part of the solid electrolytic capacitor and the semiconductor chip are connected by wire bonding, the connection part of the anode plate welded to the anode part of the solid electrolytic capacitor is not provided immediately below the connection part between the bonding wire and the anode plate or the substrate, which means they are connected in different positions when being vertically projected. This prevents the connection part between the anode plate and the anode part of the solid electrolytic capacitor from being broken down, which causes conduction failure, and achieves manufacturing of semiconductor devices with high reliability.

The above and other objects, features and advantages of the present invention will become more fully understood from the detailed description given hereinbelow and the accompanying drawings which are given by way of illustration only, and thus are not to be considered as limiting the present invention.

### BRIEF DESCRIPTION OF THE DRAWINGS

FIG. 1 is a perspective plane view showing a coating resin of a semiconductor device according to an exemplary embodiment and a first example of the present invention;

FIG. 2 is a schematic cross-sectional view taken along the line II-II of FIG. 1 according to the exemplary embodiment and the first example of the present invention;

FIG. 3 is a perspective plane view showing a coating resin of a semiconductor device according to a second example of the present invention;

FIG. 4 is a schematic cross-sectional view taken along the line IV-IV of FIG. 3 according to the second example of the present invention;

FIG. 5 is a perspective plane view of a substrate part between C-C plane and D-D plane seen from C-C plane of FIG. 4 according to the second example of the present invention;

FIG. 6 is a perspective plane view of a coating resin of a semiconductor device according to a first comparative example;

FIG. 7 is a schematic cross-sectional view taken along the line VII-VII of FIG. 6 according to the first comparative example;

FIG. 8 is a perspective plane view of a coating resin of a semiconductor device according to a second comparative example;

FIG. 9 is a schematic cross-sectional view taken along the line IX-IX of FIG. 8 according to the second comparative example; and

FIG. 10 is a cross-sectional view showing one example of a semiconductor device according to a related art.

### DESCRIPTION OF THE EXEMPLARY EMBODIMENTS

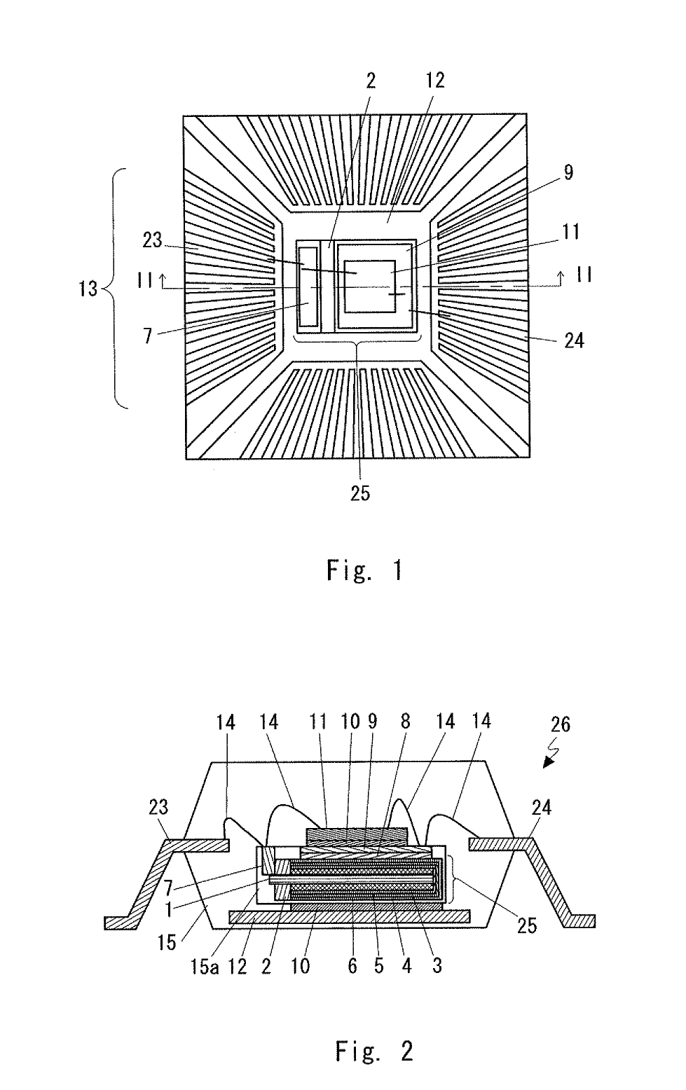

A semiconductor device according to an exemplary embodiment of the present invention will be described with reference to FIGS. 1 and 2. A semiconductor device 26 according to the exemplary embodiment of the present invention includes a solid electrolytic capacitor 25 formed of a sheet-like aluminium electrolytic capacitor, a lead frame 13, a semiconductor chip 11, and bonding wires 14. The lead frame 13 includes an island 12 formed of 42 alloy, for example, of QFP type including the solid electrolytic capacitor 25 mounted thereon, power supply leads 23, and GND leads 24. The semiconductor chip 11 is mounted on the solid electrolytic capacitor 25 with a substrate and a metallic foil 9 interposed therebetween as necessary, and has a smaller plane area than that of the solid electrolytic capacitor 25. The bonding wires 14 connect the solid electrolytic capacitor 25 and the semiconductor chip 11, and the solid electrolytic capacitor 25 and the power supply lead 23 or the GND lead 24. The bonding wire 14 is connected to an anode plate 7 or a substrate welded to an anode part 1 of the solid electrolytic capacitor 25. The semiconductor device 26 further includes a coating resin 15 that coverts the solid electrolytic capacitor 25, the metallic foil 9, and the semiconductor chip 11.

The solid electrolytic capacitor 25 includes the anode part 1 as a parent material which is a plate-like or foil-like valve action metal made of aluminium, for example, and a resist band 2 provided in the anode part 1, thereby separating an anode from a cathode and forming a base body of the solid electrolytic capacitor 25. The resist band 2 is provided in the anode part 1 of the solid electrolytic capacitor 25. A conductive polymer layer 4 is formed on a dielectric oxide coating layer 3 separated by the resist band 2, and a graphite layer 5 and a silver paste layer 6 are applied thereto and cured, thereby forming a cathode part of the solid electrolytic capacitor 25.

A method of welding the anode plate 7 to the anode part 1 of the solid electrolytic capacitor may include ultrasonic welding, resistance welding, and laser welding, and is preferably the ultrasonic welding because of its excellent production efficiency, low running cost for welding equipments, and high connection reliability. Preferably, half to two thirds of the plane area of the anode plate 7 is welded to the anode part 1. This is because it is important that the diameter of the bonding tool when connecting the bonding wire is set to be a range so that the connection part between the bonding wire and the anode plate 7 does not overlap with the part in which the anode plate 7 connects with the anode part 1 when being vertically projected. It is required that the connection part between the anode plate 7 and the anode part 1 does not overlap with the connection part between the anode plate and the bonding wire when being vertically projected, and the center of the diameter of the bonding tool is preferably the center of the range in which the bonding wire does not overlap with the connection part between the anode plate 7 and the anode part 1 when being vertically projected. The semiconductor chip may be mounted on the solid electrolytic capacitor with a substrate interposed therebetween. In this case, the whole plane area of the anode plate may be connected to the anode part. The important thing is that the diameter of the bonding tool when the bonding wire is connected to an anode pad on the substrate which is the connection part with the bonding wire does not overlap with the connection part between the anode plate and the anode part when being vertically projected. It is required that the connection part between the anode plate and the anode part and the connection part between the substrate and the bonding wire do not overlap when being vertically projected, and the center of the diameter of the bonding tool is preferably the center of the range in which the anode pad of the substrate and the connection part between the anode plate and the anode part do not overlap when being vertically projected.

The metallic foil 9 is connected, as necessary, to the solid electrolytic capacitor 25 using a silver conductive adhesive 8 so that the metallic foil 9 is provided in a part immediately below the part of the semiconductor chip 11 where the wire bonding is connected.

The anode plate 7 welded to the anode part 1 of the solid electrolytic capacitor 25 and the metallic foil 9 provided mainly on the cathode part may be made of copper, copper alloy, silver, silver alloy, gold, gold alloy, aluminum, aluminium alloy or the like, or may be one on which nickel plating or gold plating is performed using one of these materials as a parent material. The thickness including the plated part is preferably from 20 to 78 μm. The parent material of copper is preferably used because of its high conductivity. Alternatively, one that is obtained by applying a metallic foil to both surfaces of the substrate, e.g., copper-plate printed board, may be used. This may also be used as a substrate provided on the solid electrolytic capacitor. In this case, the base material of the printed board may be bismaleimide-triazine resin, glass epoxy resin, glass polyimide resin, liquid crystal polymers or the like. It is preferable that the glass epoxy resin is selected as the base material because of its wide availability, easy processing, linear expansion coefficient, the thickness of the base material is about 60 μm, copper foil applied to both surfaces of the base material is oxygen-free copper, and its thickness including the plating thickness is about 43 μm.

Thereafter, the solid electrolytic capacitor 25 is mounted on the island 12 by a non-conductive adhesive 10. Further, the semiconductor chip 11 is mounted on the substrate or the metallic foil 9 on the solid electrolytic capacitor 25 using the non-conductive adhesive 10. Then, the anode plate 7 welded to the anode part 1 of the solid electrolytic capacitor 25 and the anode part of the semiconductor chip 11 are bonded by a wire such as a gold bonding wire 14 directly or through a substrate in different positions when the connection part of the anode plate 7 welded to the anode part 1 of the solid electrolytic capacitor 25 and the connection part of the bonding wire 14 are vertically projected. The metallic foil 9 or the substrate and the cathode part of the semiconductor chip 11 are connected by wire bonding, e.g., by the gold bonding wire 14, thereafter coated by the coating resin 15.

The silver conductive adhesive 8 is used as the adhesive when the solid electrolytic capacitor 25 is not coated by a coating resin 15a, and the non-conductive adhesive 10 is used as the adhesive when the solid electrolytic capacitor 25 alone is coated by the coating resin 15a according to the connection reliability between the solid electrolytic capacitor 25 and the island 12.

While the solid electrolytic capacitor 25 according to the above exemplary embodiment has two terminals of one anode part and one cathode part, the solid electrolytic capacitor 25 may have three terminals of two anode parts and one cathode part according to the present invention.

### EXAMPLES

Hereinafter, a semiconductor device according to the present invention will be described in detail with reference to examples.

### First Example

A perspective plane view of a coating resin of a semiconductor device according to a first example corresponds to FIG. 1, which is already described above. A schematic cross-sectional structure taken along the line II-II in FIG. 1 of the semiconductor device according to the first example corresponds to FIG. 2, which is described in the exemplary embodiment. The first example will be described with reference to FIGS. 1 and 2.

First, as a roughened (etched) aluminum formation foil which is commercially available for an aluminium electrolytic capacitor, a foil having the thickness of 80 μm, the capacity per square centimeter of 118 μF, the formation voltage when forming dielectric of 9 V is selected, and punched to have a shape of a capacitor element. Next, in order to separate the anode from the cathode, epoxy resin is processed by a screen printing method to form a resist band 2 having the width of 0.8 mm and the thickness of 20 μm. The aluminum formation foil is subjected to chemical conversion in aqueous solution of adipic acid, thereby forming a dielectric oxide coating layer 3. Thereafter, chemical oxidative polymerization is performed using pyrrole as monomer, ammonium peroxodisulfate as oxidizing agent, and p-toluenesulfonic acid as dopant, thereby forming a conductive polymer layer 4 on the dielectric oxide film in the cathode forming region. The graphite layer 5 is applied thereto by a screen printing method, and cured, to have the thickness of 30 μm. Subsequently, a silver paste layer 6 is applied onto the graphite layer 5 by a screen printing method, and cured, to have the thickness of 50 μm. The anode of the anode part 1 is exposed using YAG laser, and this anode is welded, by ultrasonic welding, to the anode plate 7 of the copper parent material where copper plating with the thickness of 15 μm, nickel plating with the thickness of 3 μm, and gold plating with the thickness of 0.1 μm are performed. Two thirds of the plane area of the anode plate 7 is welded to the anode part 1.

Next, a silver conductive adhesive 8 is applied to the silver paste layer 6 of the cathode part of the solid electrolytic capacitor 25 by a dispenser, thereafter a metallic foil 9 having the length of 2.0 mm, width of 1.0 mm, and thickness of 43 μm is mounted and cured by an oxygen-free copper parent material on which nickel plating and gold plating are performed. Further, the solid electrolytic capacitor 25 is coated by transfer molding using a coating resin 15a except one side of the anode plate 7 and one side of the metallic foil 9 connected to the gold bonding wire 14 by wire bonding.

Next, a non-conductive adhesive 10, the main component of which being epoxy resin, is applied to the island 12 of the lead frame 13 of QFP type made of 42 alloy by a dispenser, and the solid electrolytic capacitor 25 is mounted and cured with the surface of the coating resin 15a being a lower surface.

Further, the non-conductive adhesive 10, the main component of which being epoxy resin, is applied onto the metallic foil 9 mounted on the cathode part of the solid electrolytic capacitor 25 by a dispenser, and the semiconductor chip 11 is mounted thereon. Then, a part in one third of an end part of the anode plate 7 which is different from the connection part with the anode part when the anode plate 7 welded to the anode part 1 of the solid electrolytic capacitor 25 is vertically projected and the anode part 1 of the semiconductor chip 11 are connected by the gold bonding wire 14 by wire bonding. Further, the metallic foil 9 and the cathode part of the semiconductor chip 11 are connected by the gold bonding wire 14 by wire bonding.

Further, a part in one third of the end part of the anode plate 7 which is different from the connection part with the anode part when the anode plate 7 welded to the anode part 1 of the solid electrolytic capacitor 25 is vertically projected and the power supply lead 23 of the lead frame 13 of QFP type are connected by the gold bonding wire 14 by wire bonding, and the metallic foil 9 and the GND lead 24 of the lead frame 13 of QFP type are connected by the gold bonding wire 14 by wire bonding.

The thus obtained ten semiconductor devices 26 are checked in terms of the connection state of the solid electrolytic capacitor and the wire bonding, and the number of devices with connection failure is counted. Table 1 shows the result. The devices are coated by the coating resin 15 using transfer molding, thereby obtaining the semiconductor device 26. The operations of the ten completed semiconductor devices 26 are tested, to check the presence or absence of breakdown of the solid electrolytic capacitor 25. Table 1 shows the result.

In the results shown in Table 1, the connection failure of the connection state between the solid electrolytic capacitor and the wire bonding means the case in which any one of the anode part and the cathode part of the semiconductor chip 11, the GND lead 24 and the power supply lead 23 of the lead frame 13 of QFP type, and the connection part by the wire bonding in the metallic foil 9 and the anode plate 7 of the solid electrolytic capacitor 25 is unconnected or disconnected. The connection failure of the connection state between the anode plate 7 and the anode part 1 of the solid electrolytic capacitor means the case in which the connection part between the anode plate 7 and the anode part 1 of the solid electrolytic capacitor that are welded by ultrasonic welding is broken down and peeled or cracked. Further, the operation failure of the semiconductor device 26 means the case in which the semiconductor chip 11 operates without the effect given by the solid electrolytic capacitor 25 embedded in the semiconductor device 26 and the case in which the semiconductor chip 11 does not operate.

### Second Example

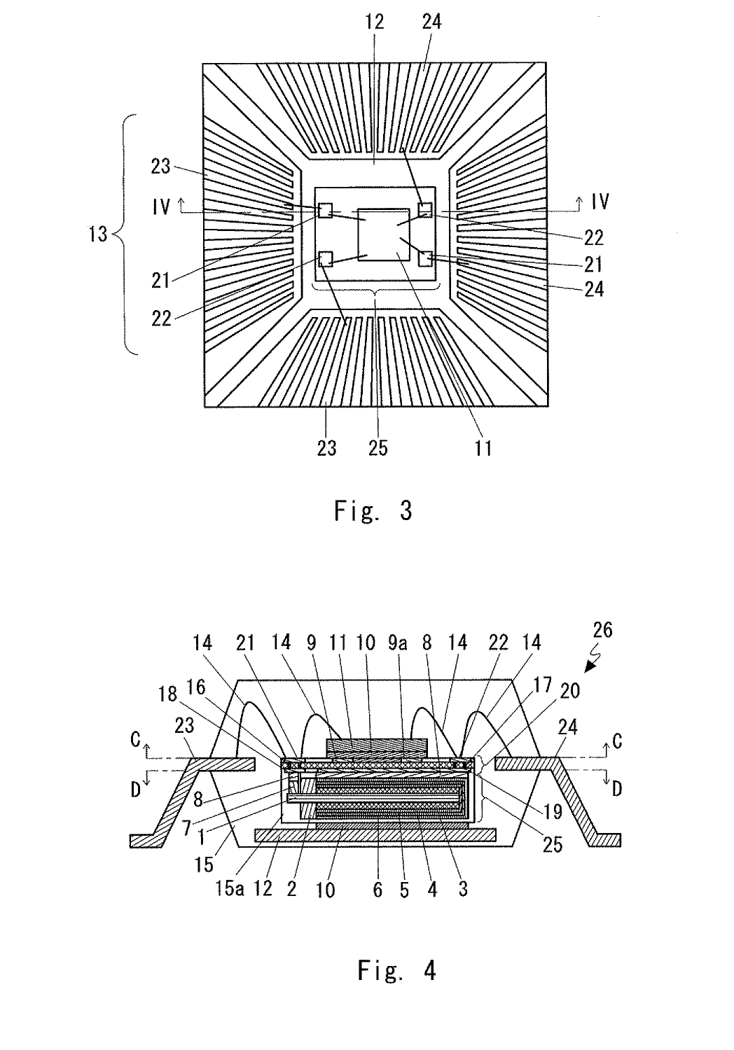

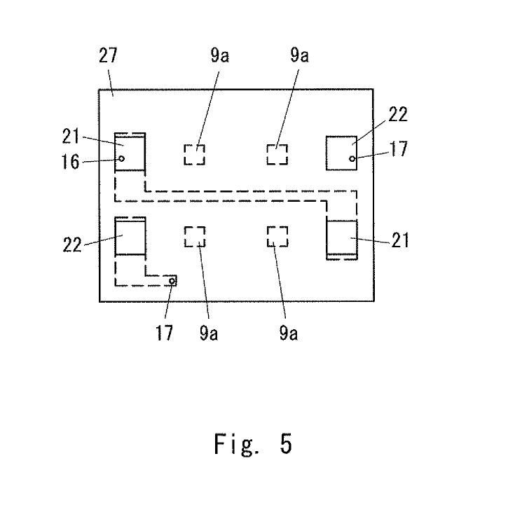

A second example will be described with reference to FIGS. 3, 4, and 5. A manufacturing process of a solid electrolytic capacitor 25 is similar to that described in the first example except the connection of the anode plate. An anode plate 7 made of a copper parent material on which copper plating with the thickness of 15 μm, nickel plating with the thickness of 3 μm, and gold plating with the thickness of 0.1 μm are performed is welded to an anode part 1 of the solid electrolytic capacitor 25 by ultrasonic welding. The whole surface of the plane area of the anode plate 7 is welded to the anode part 1.

Next, a substrate 20 is mounted on the solid electrolytic capacitor 25 in place of the metallic foil used in the first example, and a double-sided printed board with copper plate made of epoxy resin is used as the substrate 20. An anode mount part 18 and a cathode mount part 19 made of copper parent material are provided on a surface of the substrate 20 where the solid electrolytic capacitor 25 is mounted, thereby being electrically connected to two anode pads 21 and two cathode pads 22 used for the wire bonding in the side where the semiconductor chip 11 is mounted through an anode via 16 and a cathode via 17 that penetrate through the epoxy resin. Further, the substrate 20 includes four metallic foils 9a immediately below the positions of the semiconductor chip 11 where the wire bonding is connected, and other parts than the anode pads 21 and the cathode pads 22 are covered with a solder resist 27. The substrate has the length of 4.5 mm and the width of 1.6 mm. An oxygen-free copper foil having the thickness of 35 μm is arranged in both surfaces of the base material made of glass epoxy resin and having the thickness of 60 μm. Then, nickel plating with the thickness of 3 μm and gold plating with the thickness of 0.1 μm are performed, thereby obtaining the substrate 20. A silver conductive adhesive 8 is applied to the surface on the substrate 20 where the solid electrolytic capacitor 25 is mounted by a screen printing method to have a thickness of 50 μm, and the side of the solid electrolytic capacitor 25 where the anode plate 7 is welded is mounted and cured. Further, the solid electrolytic capacitor 25 is coated by a coating resin 15a using transfer molding except two anode pads 21 and two cathode pads 22 used for the wire bonding in the side where the semiconductor chip 11 is mounted.

Next, a non-conductive adhesive 10, the main component of which being epoxy resin, is applied to an island 12 of a lead frame 13 of QFP type made of 42 alloy by a dispenser, and the solid electrolytic capacitor 25 is mounted and cured with the surface of the coating resin 15a being a lower surface.

Further, the semiconductor chip 11 is mounted on the substrate 20 using the non-conductive adhesive 10, the main component of which being epoxy resin. Then, the anode part 21 used for the wire bonding of the substrate 20 on which the solid electrolytic capacitor 25 is mounted and the anode part of the semiconductor chip 11 are connected by the gold bonding wire 14 by wire bonding at a position different from the anode plate 7 of the solid electrolytic capacitor 25 when the wire bonding part of the anode pad 21 is vertically projected, which is an end part of the anode pad 21 close to the semiconductor chip 11. Further, the cathode pad 22 used for the wire bonding of the substrate 20 on which the solid electrolytic capacitor 25 is mounted and the cathode part of the semiconductor chip 11 are connected by the gold bonding wire 14 by wire bonding. Further, the anode pad 21 used for the wire bonding of the substrate 20 on which the solid electrolytic capacitor 25 is mounted is connected to the power supply lead 23 of the lead frame 13 of QFP type at a position different from the anode plate 7 of the solid electrolytic capacitor 25 when the wire bonding part is vertically projected, which is an end part of the anode pad 21 close to the power supply lead 23, and the cathode pad 22 used for the wire bonding of the substrate 20 where the solid electrolytic capacitor 25 is mounted is connected to the GND lead 24 of the lead frame 13 of QFP type by the gold bonding wire 14 by wire bonding.

The thus obtained ten semiconductor devices 26 are checked in terms of the connection state of the solid electrolytic capacitor and the wire bonding, and the number of devices with connection failure is counted. Table 1 shows the result. The devices are coated by the coating resin 15 using transfer molding, thereby obtaining the semiconductor device 26. The operations of the ten completed semiconductor devices 26 are tested, to check the presence or absence of breakdown of the solid electrolytic capacitor 25. Table 1 shows the result.

In the results shown in Table 1, the connection failure of the connection state between the solid electrolytic capacitor and the wire bonding means the case in which any one of the anode part and the cathode part of the semiconductor chip 11, the GND lead 24 and the power supply lead 23 of the lead frame 13 of QFP type, and the connection part by the wire bonding in the anode pad 21 and the cathode pad 22 used for the wire bonding in the substrate 20 used in the solid electrolytic capacitor 25 is unconnected or disconnected. The connection failure of the connection state between the anode plate 7 and the anode part 1 of the solid electrolytic capacitor means the case in which the connection part between the anode plate 7 and the anode part 1 of the solid electrolytic capacitor that are welded by ultrasonic welding is broken down and peeled or cracked. Further, the operation failure of the semiconductor device 26 means the case in which the semiconductor chip 11 operates without the effect given by the solid electrolytic capacitor 25 embedded in the semiconductor device 26 and the case in which the semiconductor chip 11 does not operate.

### First Comparative Example

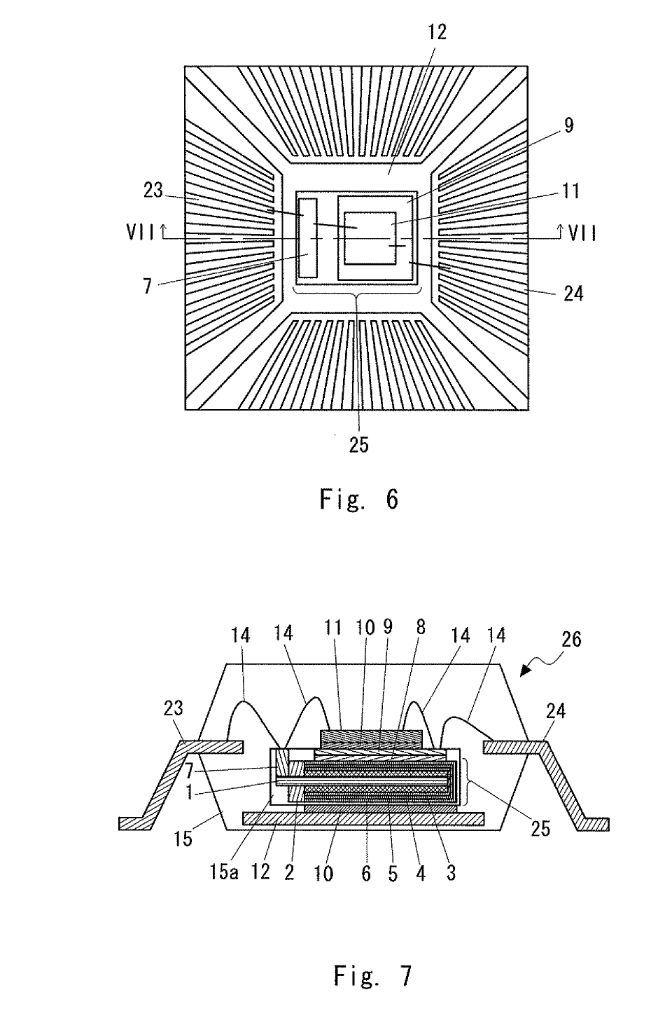

A first comparative example will be described with reference to FIGS. 6 and 7. A manufacturing process of a solid electrolytic capacitor 25 is similar to that described in the first example except the connection of the anode plate. An anode plate 7 made of a copper parent material in which copper plating with the thickness of 15 μm, nickel plating with the thickness of 3 μm, and gold plating with the thickness of 0.1 μm are performed is welded by ultrasonic welding to an anode part 1 of the solid electrolytic capacitor 25. The whole surface of the plane area of the anode plate 7 is welded to the anode part 1.

Next, similarly to the first example, a silver conductive adhesive 8 is applied onto a silver paste layer 6 of the cathode part of the solid electrolytic capacitor 25 by a dispenser, and then a metallic foil 9 with the length of 2.0 mm, the width of 1.0 mm, and the thickness of 43 μm is mounted and cured by an oxygen-free copper parent material on which nickel plating and gold plating are performed. Further, the solid electrolytic capacitor 25 is coated by transfer molding using a coating resin 15a except one side of the anode plate 7 and one side of the metallic foil 9 connected to the gold bonding wire 14 by wire bonding.

A non-conductive adhesive 10, the main component of which being epoxy resin, is applied to an island 12 of a lead frame 13 of QFP type made of 42 alloy by a dispenser, and the solid electrolytic capacitor 25 is mounted and cured with the surface of the coating resin 15a being a lower surface.

Further, the non-conductive adhesive 10, the main component of which being epoxy resin, is applied onto the metallic foil 9 mounted on the cathode part of the solid electrolytic capacitor 25 by a dispenser, and the semiconductor chip 11 is mounted thereon. Then, the anode plate 7 welded to the anode part 1 of the solid electrolytic capacitor 25 and the anode part of the semiconductor chip 11 are connected by the gold bonding wire 14 by wire bonding. The connection part between the bonding wire and the anode plate 7 is such that the connection part between the anode plate 7 and the anode part 1 of the solid electrolytic capacitor 25 is placed immediately below thereof when being vertically projected.

Further, the anode plate 7 welded to the anode part 1 of the solid electrolytic capacitor 25 and the power supply lead 23 of the lead frame 13 of QFP type are connected by the gold bonding wire 14 by wire bonding. The connection part of the bonding wire of the anode plate 7 is such that the connection part between the anode plate 7 and the anode part 1 of the solid electrolytic capacitor 25 is placed immediately below thereof when being vertically projected.

After that, the semiconductor device 26 is completed under the same condition as that in the first example. The thus obtained ten semiconductor devices 26 are checked in terms of the connection state of the solid electrolytic capacitor and the wire bonding, and the number of devices with connection failure is counted. Table 1 shows the result. The devices are coated by the coating resin 15 using transfer molding, thereby obtaining the semiconductor device 26. The operations of the ten completed semiconductor devices 26 are tested, to check the presence or absence of breakdown of the solid electrolytic capacitor 25. Table 1 shows the result.

In the results shown in Table 1, the connection failure of the connection state between the solid electrolytic capacitor and the wire bonding means the case in which any one of the anode part and the cathode part of the semiconductor chip 11, the GND lead 24 and the power supply lead 23 of the lead frame 13 of QFP type, and the connection part by the wire bonding in the metallic foil 9 and the anode plate 7 of the solid electrolytic capacitor 25 is unconnected or disconnected. The connection failure of the connection state between the anode plate 7 and the anode part 1 of the solid electrolytic capacitor means the case in which the connection part between the anode plate 7 and the anode part 1 of the solid electrolytic capacitor that are welded by ultrasonic welding is broken down and peeled or cracked. Further, the operation failure of the semiconductor device 26 means the case in which the semiconductor chip 11 operates without the effect given by the solid electrolytic capacitor 25 embedded in the semiconductor device 26 and the case in which the semiconductor chip 11 does not operate.

### Second Comparative Example

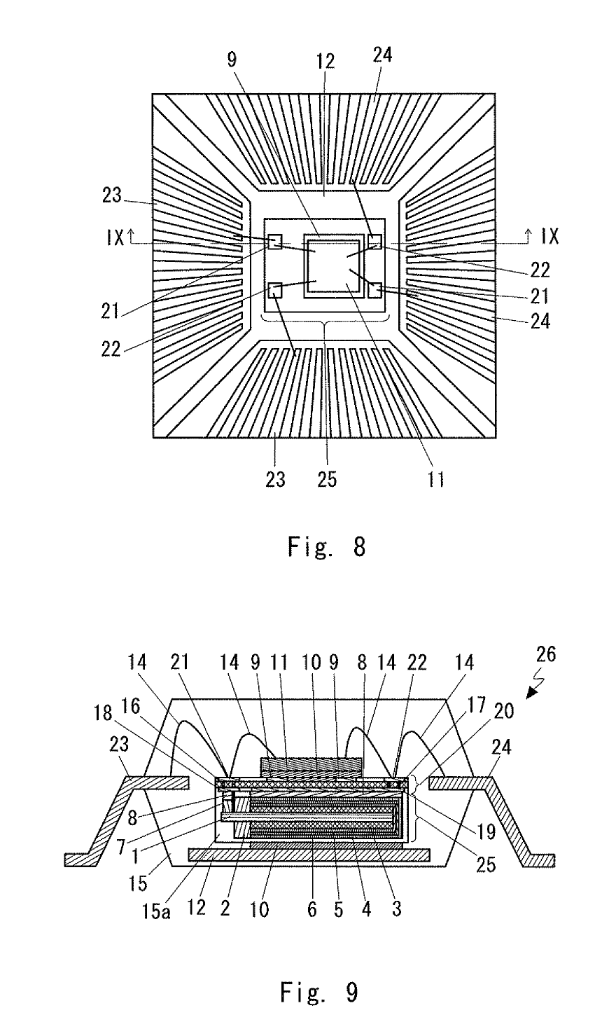

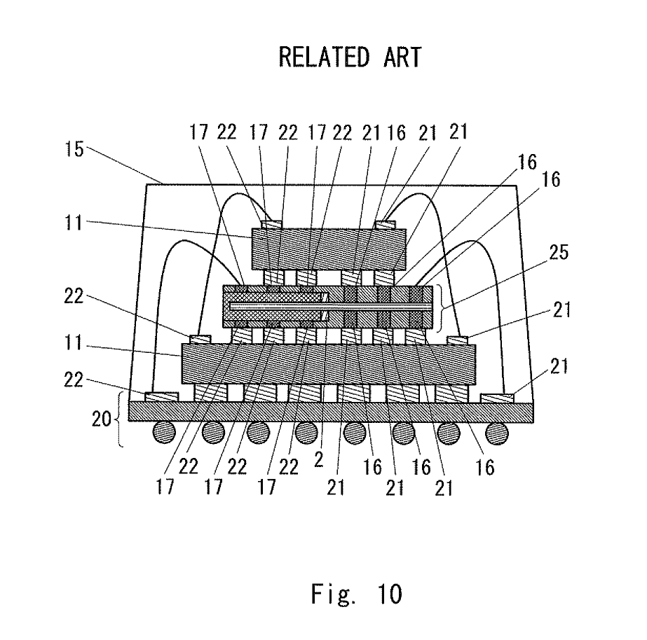

A second comparative example will be described with reference to FIGS. 8 and 9. A solid electrolytic capacitor 25 is manufactured as is similar to the second example, and a substrate 20 is mounted on the solid electrolytic capacitor 25. Then, a silver conductive adhesive 8 is applied to the surface of the substrate 20 where the solid electrolytic capacitor 25 is mounted, thereafter the side of the solid electrolytic capacitor 25 where an anode plate 7 is welded is mounted and cured. Further, the solid electrolytic capacitor 25 is coated by a coating resin 15a by transfer molding except two anode pads 21 and two cathode pads 22 used for the wire bonding in a side on which a semiconductor chip 11 is mounted.

Next, a non-conductive adhesive 10, the main component of which being epoxy resin, is applied to an island 12 of a lead frame 13 of QFP type made of 42 alloy by a dispenser, and the solid electrolytic capacitor 25 is mounted and cured with the surface of the coating resin 15a being a lower surface. Further, the semiconductor chip 11 is mounted on the substrate 20 using the non-conductive adhesive 10, the main component of which being epoxy resin.

Thereafter, the anode pad 21 used for the wire bonding of the substrate 20 on which the solid electrolytic capacitor 25 is mounted and the anode part of the semiconductor chip 11 are connected by the gold bonding wire 14 by the wire bonding. The wire bonding position of the anode pad 21 is such that the anode plate 7 connected to an anode mount part 18 of the solid electrolytic capacitor 25 by the silver conductive adhesive 8 when being vertically projected is immediately below thereof, which means they are connected by the gold bonding wire 14 at around the central part of the anode pad 21. Further, the anode pad 21 used for the wire bonding of the substrate 20 and the power supply lead 23 of the lead frame 13 of QFP type are connected by the gold bonding wire 14 by wire bonding. The wire bonding position of the anode pad 21 is immediately below the anode plate 7 connected to the anode mount part 18 of the solid electrolytic capacitor 25 by the silver conductive adhesive 8 when being vertically projected, which means they are connected by the gold bonding wire 14 at around the central part of the anode pad 21.

After that, the semiconductor device 26 is completed under the same condition as that in the second example. The thus obtained ten semiconductor devices 26 are checked in terms of the connection state of the solid electrolytic capacitor and the wire bonding, and the number of devices with connection failure is counted. Table 1 shows the result. The devices are coated by the coating resin 15 using transfer molding, thereby obtaining the semiconductor device 26. The operations of the ten completed semiconductor devices 26 are tested, to check the presence or absence of'breakdown of the solid electrolytic capacitor 25. Table 1 shows the result.

In the results shown in Table 1, the connection failure of the connection state between the solid electrolytic capacitor and the wire bonding means the case in which any one of the anode part and the cathode part of the semiconductor chip 11, the GND lead 24 and the power supply lead 23 of the lead frame 13 of QFP type, and the connection part by the wire bonding in the anode pad 21 and the cathode pad 22 used for the wire bonding of the substrate 20 used in the solid electrolytic capacitor 25 is unconnected or disconnected. The connection failure of the connection state between the anode plate 7 and the anode part 1 of the solid electrolytic capacitor means the case in which the connection part between the anode plate 7 and the anode part 1 of the solid electrolytic capacitor that are welded by ultrasonic welding is broken down and peeled or cracked. Further, the operation failure of the semiconductor device 26 means the case in which the semiconductor chip 11 operates without the effect given by the solid electrolytic capacitor 25 embedded in the semiconductor device 26 and the case in which the semiconductor chip 11 does not operate.

TABLE 1

| | | Connection state of | |
|---|---|---|---|
| | Connection state | anode plate and | Operation of |
| | of wire bonding | anode part of solid | semiconductor |
| | (number of | electrolytic capacitor | device (number |
| | devices | (number of devices | of devices |
| | with connection | with connection | with operation |
| | failure/10) | failure/10) | failure/10) |
| First | 0/10 | 0/10 | 0/10 |
| example | | | |
| First | 0/10 | 6/10 | 6/10 |
| comparative | | | |
| example | | | |
| Second | 0/10 | 0/10 | 0/10 |
| example | | | |
| Second | 0/10 | 4/10 | 4/10 |
| comparative | | | |
| example | | | |

In both of the first example and the second example, ten out of ten devices show good connection state in the solid electrolytic capacitor 25 by bonding wires in the wire bonding. Further, the operation check of the completed semiconductor devices has revealed that ten out of ten devices have normally operated. Therefore, the connection state of the anode plate and the anode part of the solid electrolytic capacitor 25 is excellent, and the connection part is not broken down.

However, according to the first comparative example, weight or impact is added at the time of wire bonding. Although the connection states of four out of ten solid electrolytic capacitors 25 are excellent, the rest of six devices have connection failure. Further, the operation check of the ten completed semiconductor devices has revealed that six out of ten devices do not operate. In the second comparative example, weight or impact is added at the time of wire bonding. The conduction states of six out of ten solid electrolytic capacitors 25 are excellent, and the rest of four devices have connection failure. Further, the operation check of the ten completed semiconductor devices has revealed that four out of ten devices do not operate.

It is therefore understood that, although the connection state of the bonding wire is excellent, the connection between the anode plate and the anode part of the solid electrolytic capacitor 25 is broken down due to the stress directly applied at the time of wire bonding.

Further, even inside the semiconductor device, the capacitor can be arranged at a part closer to the circuit of the semiconductor chip, thereby capable of improving electrical characteristics. The first example is preferable to the second example since the wiring length from the solid electrolytic capacitor to the semiconductor chip is shorter in the first example.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A semiconductor device comprising:
a lead frame comprising an island, a power supply lead, and a GND lead;
a sheet-like solid electrolytic capacitor that is mounted on the island;
a semiconductor chip that is mounted on the solid electrolytic capacitor, a plane area of the semiconductor chip being smaller than that of the solid electrolytic capacitor;
a bonding wire that connects the semiconductor chip and the solid electrolytic capacitor; and
a bonding wire that connects the solid electrolytic capacitor and the power supply lead or the GND lead,
wherein the semiconductor device includes a connection part between an anode plate welded to an anode part of the solid electrolytic capacitor and the anode part and a connection part between the anode plate and the bonding wire, the connection part between the anode plate and the anode part and the connection part between the anode plate and the bonding wire do not overlap when being vertically projected.

2. A semiconductor device comprising:
a lead frame comprising an island, a power supply lead, and a GND lead;
a sheet-like solid electrolytic capacitor that is mounted on the island;
a semiconductor chip that is mounted on the solid electrolytic capacitor through a substrate, a plane area of the semiconductor chip being smaller than that of the solid electrolytic capacitor;
a bonding wire that connects the semiconductor chip and the solid electrolytic capacitor through the substrate; and
a bonding wire that connects the solid electrolytic capacitor and the power supply lead or the GND lead through the substrate,
wherein the semiconductor device includes a connection part between an anode plate welded to an anode part of the solid electrolytic capacitor and the anode part and a connection part between the substrate and the bonding wire, the connection part between the anode plate and the anode part and the connection part between the substrate and the bonding wire do not overlap when being vertically projected.

3. The semiconductor device according to claim 1, wherein a main component of a parent material of the anode plate is copper.

4. The semiconductor device according to claim 2, wherein a main component of a parent material of the anode plate is copper.
